(19) United States
(12) Patent Application Publication
(10) Pub. No.: US 2009/0078953 A1
(43) Pub. Date: Mar. 26, 2009

(54) LIGHT EMITTING DIODE PACKAGE STRUCTURE

(76) Inventor: Hsin-Hui YEH, Hsinchu City (TW)

Correspondence Address: SINORICA, LLC, 528 FALLSGROVE DRIVE, ROCKVILLE, MD, 20850, US

(21) Appl. No.: 12/053,613

(22) Filed: Mar. 23, 2008

(30) Foreign Application Priority Data
Aug. 24, 2007 (TW) 096131343

(51) Int. Cl. H01L 33/00

(52) U.S. Cl. 257/98; 257/E33.058

(57) ABSTRACT

The present invention provides a light emitting diode (LED) package, which includes a carrier substrate having a first surface and a second surface; a metal layer formed in the first surface of the carrier substrate, and a through hole formed in the central area of the metal layer to expose the portion of the first surface of the carrier substrate; a LED having a semiconductor layer capable of light emitting, and an N electrode and a P electrode on the two sides of the semiconductor layer, in which P electrode is electrically connected to the first surface of the metal layer; a first connecting element is electrically connected to the metal layer; a second connecting element is electrically connected to the N electrode; and an encapsulated material is formed to cover the LED, the metal layer, the exposed first connecting element and the second connecting element.

### BACKGROUND OF THE INVENTION

1. Field of the Invention

The present invention is a light emitting diode (LED) package structure and more particularly is a package structure that the LED is electrically connected to a metal layer on a transparent substrate.

2. Description of the Prior Art

Light emitting diode (LED) is widely used in any electronic devices and is more popular in the industry. The energy consumption of the LED is lower than the conventional incandescent lamp or fluorescent lamp and the size of the LED is smaller than the conventional lamp. Therefore, the demand of the LED is increased day after day because the trend of the size of the electronic products is smaller and smaller.

LED is a light emitting element used to directly transform the electrical power to light power without the heating and luminescent procedure of transforming the electrical power to heat power. Therefore, LED is also called the luminescence emitting element. LED not only includes high luminance efficiency but also is a micro solid state illuminator made in a semiconductor chip form. The semiconductor chip form includes a semiconductor p-n junction structure. The voltage is inputted in two sides of the p-n junction and the current is able to flow through to generate electrons and holes flowing toward the p-n junction, and the electrons and holes are connected with the p-n junction to release photons.

Generally, the illumination of the LED in the present art is equal to or half of the efficiency of the illumination of the cold cathode fluorescent lamp. The illumination efficiency of the LED is related to: the illumination efficiency of the semiconductor chip itself and the extraction efficiency of the semiconductor chip package structure. The development of the illumination efficiency is to invent the electroluminescent material and to increase the crystallizability of the semiconductor chip to enhance the quantum efficiency inside the semiconductor chip.

According to the description above, the LED is a light source with lower power consumption than the conventional incandescent lamp or fluorescent lamp and the size of LED is smaller and lighter than the conventional lamps. But how to enhance the extraction efficiency of the LED package structure to get higher overall efficiency in the quantum efficiency inside the semiconductor chip of the LED is the important issue in current technology.

### SUMMARY OF THE INVENTION

According to the problems described above, the main object of the present invention is to provide a transparent substrate to package with the light emitting diode (LED) at the same time and shorten the LED package time to reduce the process period and cut the package cost.

The other object of the present invention is to connect the LED with the transparent substrate and increase the liability of the elements.

According the objects describe above, the present invention discloses a light emitting diode (LED) package structure comprises a carrier substrate, a metal layer, a LED, a first connecting element, a second connecting element, and an encapsulated material. The carrier substrate includes a first surface and a second surface. The metal layer includes a top surface and a bottom surface, and the bottom surface is connected to the first surface of the carrier substrate and a central region of the metal layer includes a through hole passing through the top surface and the bottom surface, and a portion of the first surface of the carrier substrate can be exposed. The LED including an N electrode and a P electrode disposed at two sides of the semiconductor layer and the P electrode is electrically connected to a portion of the top surface of the metal layer. The first connecting element is electrically connected to another portion of the top surface of the metal layer. The second connecting element is electrically connected to the N electrode of the LED. The encapsulated material covers the LED, the metal layer, a portion of the first connecting element and a portion of the second connecting element, and the other portion of the first connecting element and the second connecting element are exposed over the encapsulated material.

The present invention also discloses a LED package structure comprises a carrier substrate, a patterned metal layer, a LED, a pair of connecting elements and an encapsulated material. The carrier substrate includes a first surface and a second surface. The patterning metal layer is disposed on the first surface of the carrier substrate. The LED includes an N electrode and a P electrode disposed at two sides of the semiconductor layer and the P electrode and the N electrode are respectively and electrically connected to a portion of the top surface of the patterned metal layer by a metal material. The pair of conductive connecting elements, each of the conductive connecting elements includes a first end, which is electrically connected to the patterned metal layer. The encapsulated material covers the LED, the patterned metal layer and a portion of the conductive connecting elements, and the other portion of the conductive connecting elements are exposed over the encapsulated material.

The detailed description of the present invention will be discussed in the following embodiments, which are not intended to limit the scope of the present invention, but can be adapted for other applications. While drawings are illustrated in details, it is appreciated that the quantity of the disclosed elements may be greater or less than that disclosed, except expressly restricting the amount of the elements.

### BRIEF DESCRIPTION OF THE DRAWINGS

FIG. 1 is sectional view of the light emitting diode (LED) according to an embodiment of the present invention.

FIG. 2 is a sectional view of the light emitting diode (LED) according to another embodiment of the present invention.

FIG. 3A is a vertical view showing that the patterning metal layer is disposed on the carrier substrate.

FIG. 3B is a sectional view of FIG. 3A.

FIGS. 4A-4C are views showing that the package steps of the LED structure.

FIG. 5 is a sectional view showing that the package structure of LED and the light focusing mask.

FIG. 6A is a vertical view showing that the patterning metal layer is disposed on the carrier substrate.

FIG. 6B is a sectional view of FIG. 6A.

FIGS. 7A-7C are views showing that the package steps of the LED structure.

FIGS. 8A-8B are views showing that the package steps of the connecting element formed on the patterning metal layer.

FIGS. 9A-9B are sectional views showing that the package structure of LED and the light focusing mask.

### DESCRIPTION OF THE PREFERRED EMBODIMENT

The following detailed description of the present invention describes a light emitting diode package structure necessary to provide an understanding of the present invention, but does not cover a complete structure composition and the operating theory. The portions relating to the conventional techniques are briefly described, and the parts of the drawings are not proportionally drafted. While embodiments are discussed, it is not intended to limit the scope of the present invention. Except expressly restricting the amount of the components, it is appreciated that the quantity of the disclosed components may be greater than that disclosed.

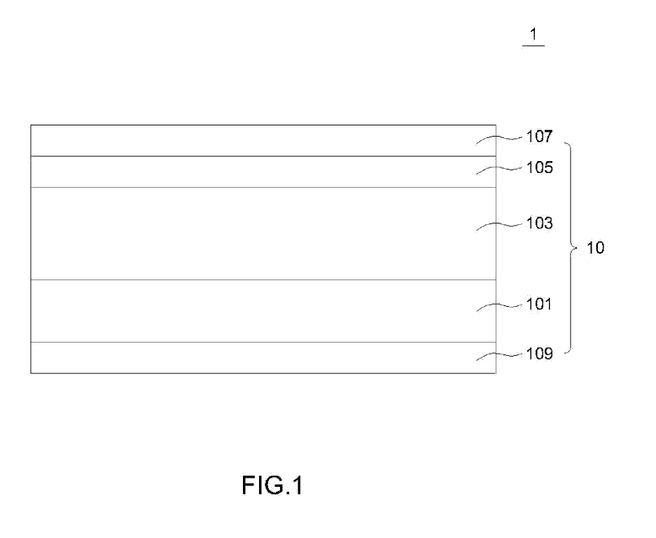

First of all, please referring to FIG. 1; it is a view showing that the light emitting diode (LED) structure of the present invention. The LED structure 10 includes a semiconductor layer 103 with light emitting function. There are an N electrode 107 and a P electrode 109 disposed on the two sides of the semiconductor layer 103. The LED structure 10 further includes a substrate 101 disposed between the P electrode 109 and the semiconductor layer 103 and a transparent conductive layer 15 disposed between the N electrode 107 and the semiconductor layer 103.

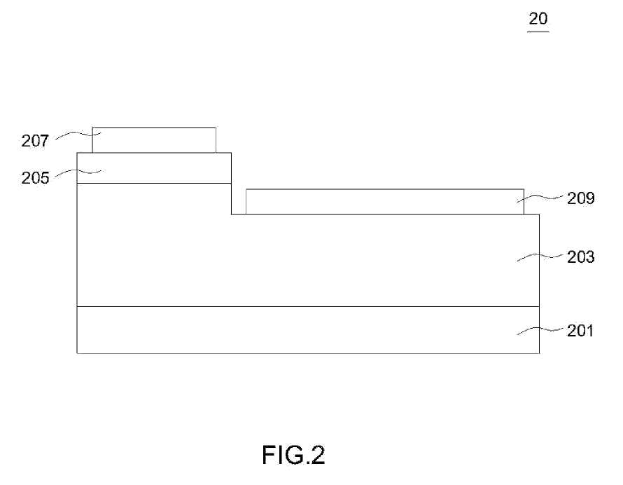

Referring to FIG. 2, it is another LED structure of the present invention. The LED structure 20 includes a semiconductor layer 203 with light emitting function. There are an N electrode 207 and a P electrode 209 disposed at the same side of the semiconductor layer 203. In addition, the LED structure 20 further includes a substrate formed below the semiconductor layer 203 and a transparent layer 205 disposed between the semiconductor layer 205 and the N electrode 207.

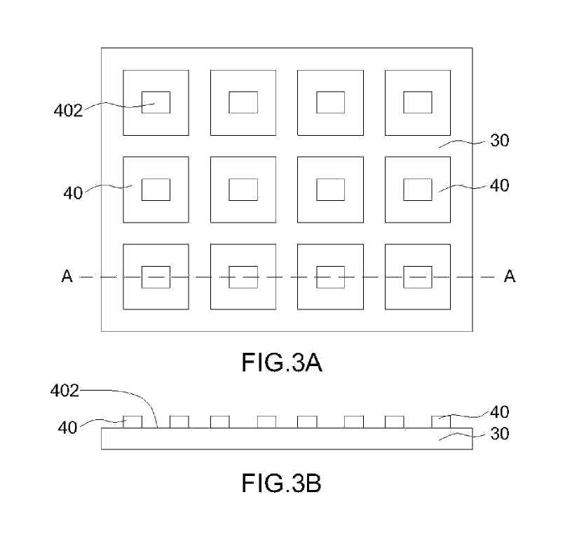

FIG. 3A and FIG. 3B are a vertical view and a sectional view in the present invention. As shown in FIG. 3A, it is a carrier substrate 30 including a first surface and a second surface. The carrier substrate 30 is made by a transparent material, such as glass or optical glass. Still referring to FIG. 3A, a plurality of the patterned metal layers 40 disposed on the top surface of the carrier substrate 30. The central region of the patterned metal layers 40 includes a through hole passing through the top surface and the bottom surface of the carrier substrate 30 and is used to expose a portion of the top surface of the carrier substrate 30.

The method to form the patterned metal layer 40 on the carrier substrate 30 is forming a metal layer on the carrier substrate 30 and then coating a photoresist layer (not shown) on the metal layer. A patterned photoresist layer is formed on the metal layer after exposing by a patterning mask. Then, an eroding step is used to remove a portion of the metal layer and the photoresist layer is removed to form a plurality of patterned metal layers 40 on the carrier substrate 30. The central region in each of the metal layers 40 includes a through hole 402 used to be the exit for the light of the light emitting diode.

As shown in FIG. 3B, it is a A-A sectional view of the FIG. 3A. Similarity, The carrier substrate 30 includes a first surface and a second surface. The first surface of the carrier substrate 30 includes a plurality of patterned metal layers 40 and through holes 402.

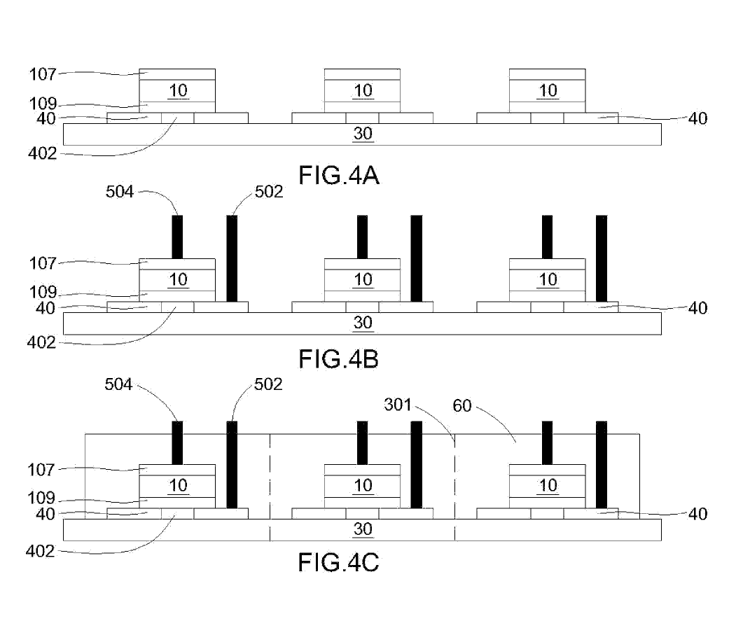

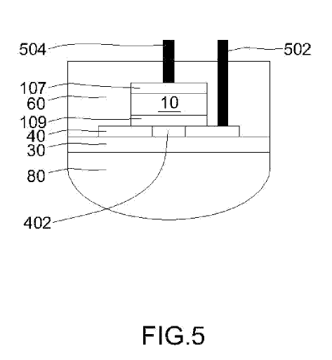

FIGS. 4A to 4C is a view showing that the package steps of the light emitting diode (LED). As shown in FIG. 4A, the P electrode of the LED is electrically coupled on a portion of the top surface of the patterned metal layer 40. In this embodiment, the P electrode 109 of the LED is electrically connected to the patterned metal layer 40 by conductive material, such as solder paste. It should be noted that the LED's light can be green light, red light or blue light in the embodiment of the present invention. In other word, no matter what LED can emit green light, red light or blue with the package structure shown in FIG. 1 included in the present invention.

As shown in FIG. 4B, there is a plurality of connecting elements. Some of the connecting elements 502 are formed on the patterned metal layer 40 and electrically connected to the patterned metal layer 40. The other of the connecting elements 504 are electrically connected to the N electrode 107 of the LED 10. It should be noted that the connecting elements 502/504 disclosed in the present invention are golden fingers or metal leads. When the connecting elements 502/504 are golden fingers, the isolated material (such as plastic) or the ceramic material is used to cover the connecting elements 502/504. Therefore, as the description above, the connecting elements 502 are electrically connected to the patterned metal layer 40 or the connecting elements 504 are electrically connected to the N electrode 107 by using the conductive material, such as solder paste.

Please referring to FIG. 4C, an encapsulated material is injected into the package structure shown in FIG. 4B. The encapsulated material is used to cover the LED 10, the patterned metal layer 40 and the connecting elements. Some of the connecting elements 502/504 are exposed outside the encapsulated material and used to be power connection. The encapsulated material 60 is an epoxy or colloid in the embodiment of the present invention.

After the steps in FIG. 4C were done, the sawing process for the carrier substrate 30 is in proceeding. The transparent carrier substrate 30 and the encapsulated material 60 are cut according to the sawing line 301 on the carrier substrate 30 to form a plurality of packaged LED. It is obvious that the LED in the present invention is molding by the transparent carrier substrate 30 and the encapsulated material 60 and is connected to a power source by the exposed connecting elements. Therefore, the LED is illuminable. However, in order to enhance the illumination of the LED and let all the LED light has the same light focus direction; a light focusing mask 80 is used in the embodiment of the present invention and disposed on the packaged LED structure. There is a reflective surface (not shown) disposed on the inner side of the light focusing mask 80 and used to form a better light reflective path to enhance the illumination. It should be noted that the step to add a light focusing mask 80 is similar to a conventional LED package process. After the LED package structures are cut into an individual one, the individual LED is adding a light focusing mask. The way to add a light focusing mask is by gluing or coupling. Moreover, the material (such as plastic) of the light focusing mask 80 is not limited in the present invention. Besides, in the embodiment of the present invention, after the steps in FIG. 4C were done, the step to glue or couple a light focusing mask 80 is preceded. The light focusing mask 80 is connected to the second surface of the packaged LED structure, as shown in FIG. 5. It is obvious that the step of adding the light focusing mask 80 can avoid the LED being polluted. The reflective surface (not shown) disposed on the inner side of the light focusing mask 80 can be used to enhance the illumination.

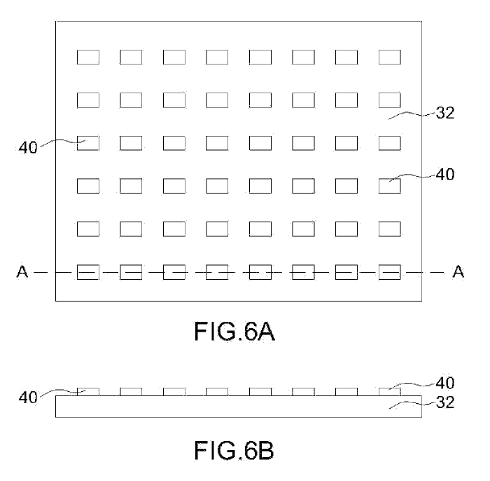

In addition, there is another LED package structure and method thereof. As shown in FIG. 6A, there is a transparent carrier substrate 32 including a first surface and a second surface. The first surface of the transparent carrier substrate 32 includes a plurality of patterning metal point 40. FIG. 6B is AA sectional view according to FIG. 6A.

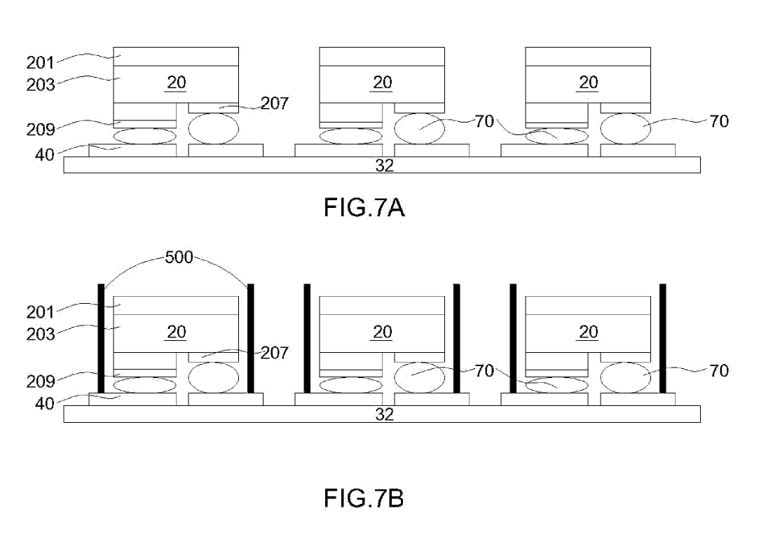

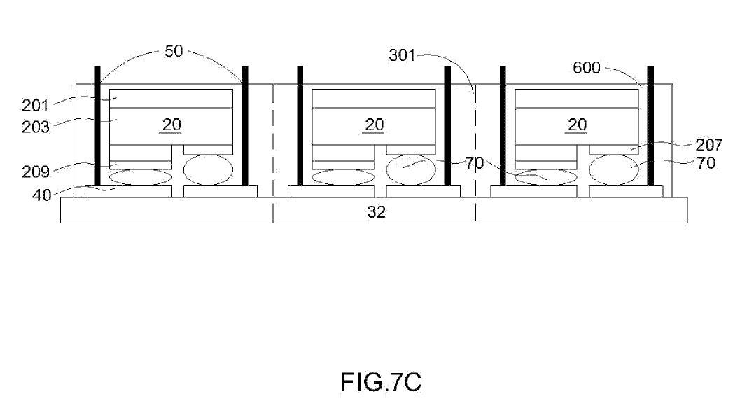

FIGS. 7A to 7C are views showing that the steps of the LED package structure. As shown in FIG. 7A, the LED structure 20 includes a semiconductor layer 203 with light emitting function. There are an N electrode 207 and a P electrode 209 disposed on the same sides of the semiconductor layer 203. The N electrode 207 and the P electrode 209 are electrically connected to the top of the first surface of the patterning metal point 40. In the embodiment of the present invention, the N electrode 207 and the P electrode 209 of the LED 20 are electrically connected to the patterned metal point 40 by the connecting element 70, such as metal bump or solder ball.

Referring to FIG. 7B, a plurality of connecting elements 50 are shown herein. The connecting elements 50 are electrically connected to the top surface of the patterned metal point 40. As the description above, the connecting elements 50 are gold fingers. When the connecting elements 50 are golden fingers, the isolated material (such as plastic) or the ceramic material can be used to cover the connecting elements 50. In addition, in different embodiment, the connecting elements 50 are metal lead used to electrically connect to the top surface of the patterned metal point 40.

Please referring to FIG. 7C, an encapsulated material is injected into the package structure shown in FIG. 7B. The encapsulated material 600 is used to cover the LED 20, the patterned metal point 40 and the connecting elements 50. Some of the connecting elements 50 are exposed on the encapsulated material and used to be power connection. The encapsulated material 600 is an epoxy or colloid in the embodiment of the present invention.

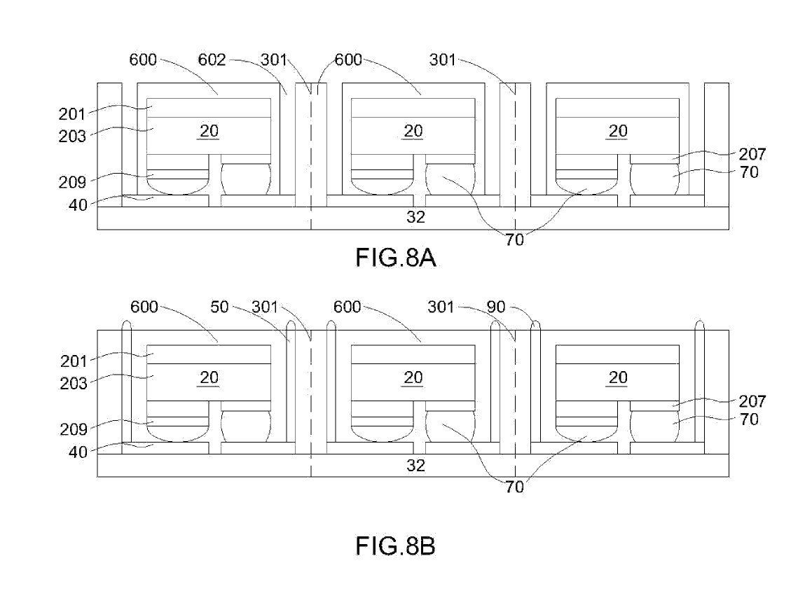

In addition, there is another embodiment showing that the connecting elements formed on the patterned metal layer in the present invention. As shown in FIGS. 8A and 8B, in the embodiment, after a plurality of LED 20 are electrically connected to a plurality of the patterned metal point 40 on the transparent carrier substrate 32, a molding process is used to form a encapsulated material 600 for covering the LEDs 20 and the patterned metal point 40. After the alignment process, the eroding step, such as dry eroding or reactive ion eroding (RIE), is used to remove a portion of the encapsulated material 600 on the patterned metal layer and a plurality of through holes 602 are formed to expose a portion of the first surface of the patterned metal point 40. By using the plating method, the conductive materials are filled in those through holes 602 to form a plurality of connecting elements 50. After a plurality of conductive elements 90 are formed on a plurality of connecting elements 50, the package steps of the LED were done. Similarity, the conductive elements in the present embodiment are solder ball or solder bump.

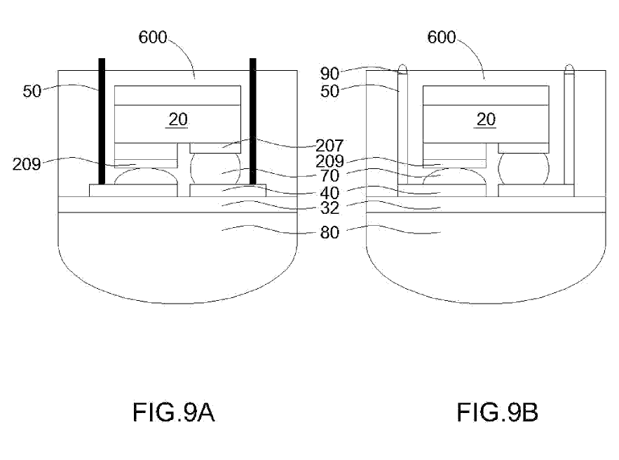

After the steps shown in FIGS. 7C and 8B were done, the sawing process is used to cut the transparent carrier substrate 30 and the encapsulated material 600 by the sawing line 301 of the carrier substrate 30 to form a plurality of the packaged LED elements. The LED package structure in the present invention is covered by the carrier substrate 30 and the encapsulated material 600. The LED light is able to turn on by connecting the connecting elements exposed on the encapsulated material 600 to the power source. However, in order to enhance the illumination of the LED and let the LED has the same light focus direction; a light focusing mask 80 is used in the embodiment of the present invention and disposed on the packaged LED structure 20. There is a reflective surface (not shown) disposed on the inner side of the light focusing mask 80 and used to form a better light reflective path to enhance the illumination. It should be noted that the step to add a light focusing mask 80 is similar to a conventional LED package process. After the LED package structures are cut into an individual one, the individual LED is adding a light focusing mask. The way to add a light focusing mask is by gluing or coupling. Moreover, the material (such as plastic) of the light focusing mask 80 is not limited in the present invention. Besides, in the embodiment of the present invention, after the steps in FIG. 4C were done, the step to glue or couple a light focusing mask 80 is preceded. The light focusing mask 80 is connected to the second surface of the packaged LED structure, as shown in FIGS. 9A and 9B. It is obvious that the step of adding the light focusing mask 80 can avoid the LED being polluted. The reflective surface (not shown) disposed on the inner side of the light focusing mask 80 can be used to enhance the illumination.

Although specific embodiments have been illustrated and described, it will be appreciated by those skilled in the art that various modifications may be made without departing from the scope of the present invention, which is intended to be limited solely by the appended claims.

What is claimed is:

1. A light emitting diode (LED) package structure comprising:
a carrier substrate having a first surface and a second surface;
a metal layer having a top surface and a bottom surface, and the bottom surface is connected to the first surface of the carrier substrate and a central region of the metal layer includes a through hole passing through the top surface and the bottom surface, and a portion of the first surface of the carrier substrate is to be exposed;
a LED having an N electrode and a P electrode disposed at two sides of the semiconductor layer and the P electrode is electrically connected to a portion of the top surface of the metal layer;
a first connecting element electrically connected to another portion of the top surface of the metal layer;
a second connecting element electrically connected to the N electrode of the LED; and
an encapsulated material covering the LED, the metal layer, a portion of the first connecting element and a portion of the second connecting element, and the other portion of the first connecting element and the second connecting element are exposed over the encapsulated material.

2. The package structure of claim 1, further comprising a light focusing mask formed on the second surface of the carrier substrate.

3. The package structure of claim 1, wherein the carrier substrate is a transparent substrate.

4. The package structure of claim 3, wherein the transparent substrate is a glass.

5. The package structure of clam 1, wherein the P electrode of the LED is electrically connected to the metal layer by conductive glue.

6. The package structure of claim 1, wherein the first connecting element and the second connecting element are golden fingers.

7. The package structure of claim 1, wherein the first connecting element and the second connecting element are metal leads.

8. The package structure of claim 1, wherein the first connecting element and the second connecting element are electrically connected to the N electrode and the metal layer by conductive glue.

9. The package structure of claim 1, wherein the encapsulated material is an epoxy.

10. The package structure of claim 1, wherein the encapsulated material is a colloid.

11. A LED package structure comprising:
a carrier substrate having a first surface and a second surface;
a patterned metal layer having a top surface and a bottom surface, and the bottom surface is connected to the first surface of the carrier substrate and a second region of the metal layer includes a through hole passing through the top surface and the bottom surface and a portion of the first surface of the carrier substrate is to be exposed;
a LED including an N electrode and a P electrode disposed at two sides of the semiconductor layer and the P electrode is electrically connected to a portion of the top surface of the metal layer;
a pair of connecting elements respectively and electrically connected to the patterned metal layer; and
an encapsulated material covering the LED, the patterned metal layer and a portion of the conductive connecting elements, and the other portion of the conductive connecting elements are exposed on the encapsulated material.

12. The package structure of claim 11, further comprising a light focusing mask formed on the second surface of the carrier substrate.

13. The package structure of claim 11, wherein the carrier substrate is a transparent substrate.

14. The package structure of claim 13, wherein the transparent substrate is a glass.

15. The package structure of claim 11, wherein the connecting elements are solder ball.

16. The package structure of claim 11, wherein the connecting elements are metal bump.

17. The package structure of claim 11, wherein the connecting element s are golden fingers.

18. A LED package structure comprising:
a carrier substrate having a first surface and a second surface;
a patterned metal layer disposed on the first surface of the carrier substrate;
a LED having an N electrode and a P electrode disposed at two sides of the semiconductor layer and the P electrode and the N electrode are respectively and electrically connected to a portion of the top surface of the patterned metal layer by a metal material;
a pair of conductive connecting elements, each of the conductive connecting elements includes a first end, which is electrically connected to the patterning metal layer; and
an encapsulated material covering the LED, the patterned metal layer and a portion of the conductive connecting elements, and the other portion of the conductive connecting elements are exposed over the encapsulated material.

19. The package structure of claim 18, wherein the carrier substrate is a transparent substrate.

20. The package structure of claim 18, further comprising a light focusing mask formed on the second surface of the carrier substrate.
